(19) United States
(12) Patent Application Publication
(10) Pub. No.: US 2007/0273002 A1
(43) Pub. Date: Nov. 29, 2007

(54) Semiconductor Memory Devices Having Fuses and Methods of Fabricating the Same

(75) Inventor: Min-Wk Hwang, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/753,114

(22) Filed: May 24, 2007

(30) Foreign Application Priority Data
May 29, 2006 (KR) 2006-48288

(51) Int. Cl. H01L 29/00; H01L 21/82

(52) U.S. Cl. 257/529; 438/132; 257/E23.149

(57) ABSTRACT

An integrated circuit device is provided with a plurality of normally open fuse elements. A fuse element includes a fuse insulation film lining a sidewall and a bottom of a recess in a semiconductor substrate. A semiconductor fuse region of first conductivity type (e.g., N-type) is provided in the semiconductor substrate. The semiconductor fuse region extends to the sidewall of the recess. A fuse conductor is provided on a portion of the fuse insulation film extending opposite the semiconductor fuse region. A voltage induced rupture in the fuse insulation film results in a direct electrical connection between the fuse conductor and the semiconductor fuse region.

### REFERENCE TO PRIORITY APPLICATION

This application claims priority under 35 U.S.C. § 119 to Korean Patent Application No. 2006-48288, filed May 29, 2006, the entire contents of which are hereby incorporated herein by reference.

### FIELD OF THE INVENTION

The present invention relates to semiconductor device technology and more particularly, to semiconductor memory devices having fuses and methods of fabricating the same.

### BACKGROUND OF THE INVENTION

Semiconductor memory devices are often organized with many millions of memory cells. In order to increase device yield, there have been proposed techniques for replacing defective memory cells with redundant or spare memory cells. In order to perform a repair process for replacing defective cells with redundant cells, a semiconductor memory device is usually equipped with a fuse circuit. By connecting or disconnecting a fuse in a fuse circuit, it is possible to replace defective cells with redundant cells. Typically, fuses are formed as metal lines. A defective cell is replaced with a redundant cell by cutting off a fuse by means of laser.

FIG. 1 is a sectional view illustrating a general semiconductor memory device. Referring to FIG. 1, a lower interlevel oxide film 2 is placed on a semiconductor substrate 1 and a fuse line 3 is arranged on the lower interlevel oxide film 2. The fuse line 3 may be made of aluminum (Al). An upper interlevel oxide film 4 covers the semiconductor substrate 1 including the fuse line 3 and a passivation layer 5 covers the upper interlevel oxide film 4. The passivation film 5 may function to protect the semiconductor memory device from various pollutants such as vapor, particles, and so on. An opening 6 exposes the fuse line 3 by penetrating the passivation film 5 and the upper interlevel oxide film 4. Repairing a defective cell is accomplished by cutting off the fuse line 3 by irradiating with a laser through the opening 6.

However, with a trend towards higher integration, the fuse line 3 may become narrower in width and the opening 6 may become smaller in area. Thus, during a repair process, the fuse line 3 may not be blown out by the laser, and the repair of a defective memory cell may not be reliable achieved.

### SUMMARY OF THE INVENTION

Embodiments of the present invention include integrated circuit devices (e.g., memory devices) having fuse elements therein. According to some of these embodiments, an integrated circuit device is provided with a plurality of normally open fuse elements. A fuse element includes a fuse insulation film lining a sidewall and a bottom of a recess in a semiconductor substrate. A semiconductor fuse region of first conductivity type (e.g., N-type) is also provided in the semiconductor substrate. The semiconductor fuse region extends to the sidewall of the recess. A fuse conductor is provided on a portion of the fuse insulation film extending opposite the semiconductor fuse region. A voltage induced rupture in the fuse insulation film results in a direct electrical connection between the fuse conductor and the semiconductor fuse region.

A relatively thick trench-based fuse isolation region may also be provided. This fuse isolation region extends in the semiconductor substrate and defines a semiconductor fuse active region therein, which contains the recess. The fuse conductor fills the recess and extends onto an upper surface of the trench-based fuse isolation region. The recess may be surrounding on at least three sides by the semiconductor fuse region. Moreover, the recess may be formed so that a lower portion of the sidewall is recessed relative to an upper portion of the sidewall.

According to additional embodiments of the invention, the fuse insulation film includes an insulation extension that extends from the sidewall onto an upper surface of the semiconductor fuse region. The fuse conductor may also extend onto the insulation extension. The fuse insulation film may also have a nonuniform thickness adjacent a corner between the sidewall and the upper surface of the semiconductor fuse region.

Still further embodiments of the invention include methods of forming a fuse element of an integrated circuit device. These methods include forming a trench-based fuse isolation region in a semiconductor substrate and forming a recess in the semiconductor substrate, adjacent a sidewall of the trench-based fuse isolation region. A fuse insulation film is also provided. The fuse insulation film lines a bottom and a sidewall of the recess. The recess is also filled with a fuse conductor and a semiconductor fuse region is formed in the substrate. The semiconductor fuse region extends to the sidewall of the recess. According to additional aspects of these embodiments, an electrically insulating layer may be formed on the semiconductor fuse region and on the fuse conductor. The electrically insulating layer may be patterned to define first and second openings therein that expose the semiconductor fuse region and the fuse conductor, respectively. First and second contact plugs are then formed in the first and second openings, respectively.

According to still further embodiments of the present invention, a method of forming a fuse element includes forming a semiconductor fuse region of first conductivity type adjacent a surface of a semiconductor substrate and forming a trench-based fuse isolation region that extends through the semiconductor fuse region. A step is then performed to form a recess that extends through the semiconductor fuse region, adjacent a sidewall of the trench-based fuse isolation region. A fuse insulation film is then formed. The fuse insulation film lines a bottom and a sidewall of the recess and extends onto the semiconductor fuse region. The electrically conductive layer is deposited onto the fuse insulation film. The electrically conductive layer and the fuse insulation film are patterned to expose the semiconductor fuse region and define a fuse conductor that fills the recess and extends onto the semiconductor fuse region. First and second terminals of the fuse element are then formed. These first and second terminals (e.g., conductive plugs and wiring interconnects) are electrically connected to the semiconductor fuse region and the fuse conductor, respectively.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a sectional view illustrating a conventional semiconductor memory device;

FIG. 2 is a plan view illustrating a semiconductor memory device in accordance with an embodiment of the present invention;

FIG. 3A is a sectional view taken along lines I-I′, II-II′, and III-III′ of FIG. 2;

FIG. 3B is a sectional view taken along lines I-I′, II-II′, and III-III′ of FIG. 2, illustrating a modification of the semiconductor memory device in accordance with an embodiment of the present invention;

FIG. 4 is a plan view illustrating another modification of the semiconductor memory device in accordance with an embodiment of the present invention;

FIG. 5 is a sectional view taken along line IV-IV′ of FIG. 4;

FIGS. 6 through 10 are sectional views taken along lines I-I′, II-II′, and III-III′ of FIG. 2, illustrating a method of fabricating a semiconductor memory device, in accordance with an embodiment of the present invention;

FIGS. 11 through 15 are sectional views taken along lines I-I′, II-II′, and III-III′ of FIG. 2, illustrating a method of fabricating the semiconductor memory device shown in FIG. 3B; and

FIGS. 16 and 17 are sectional views taken along line IV-IV′ of FIG. 4, illustrating a method of fabricating the semiconductor memory device shown in FIG. 4 or FIG. 5.

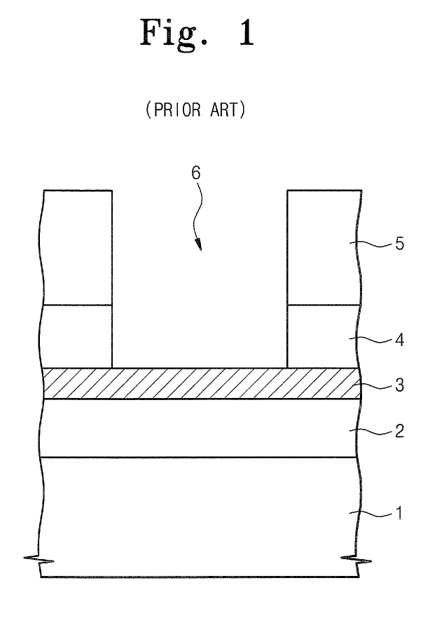

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Moreover, the description hereinbelow uses tenns of first, second, or third for representing pluralities of various regions or films, those terms are employed to differentiate one from another, not restrictive thereto. In a certain case, a first region or film may be referred to as a second region or film in another embodiment. And, embodiments described herein may include their complementary cases. In the figures, like reference numerals refer to like elements throughout.

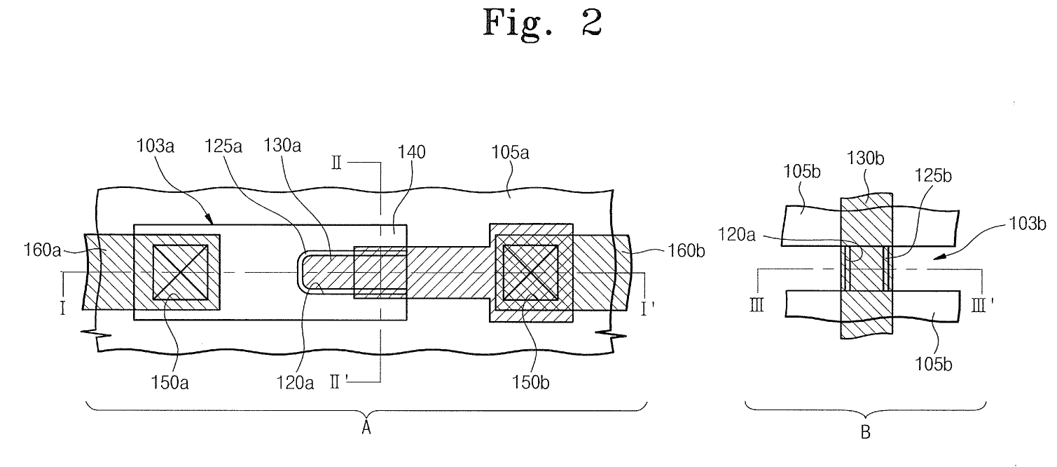

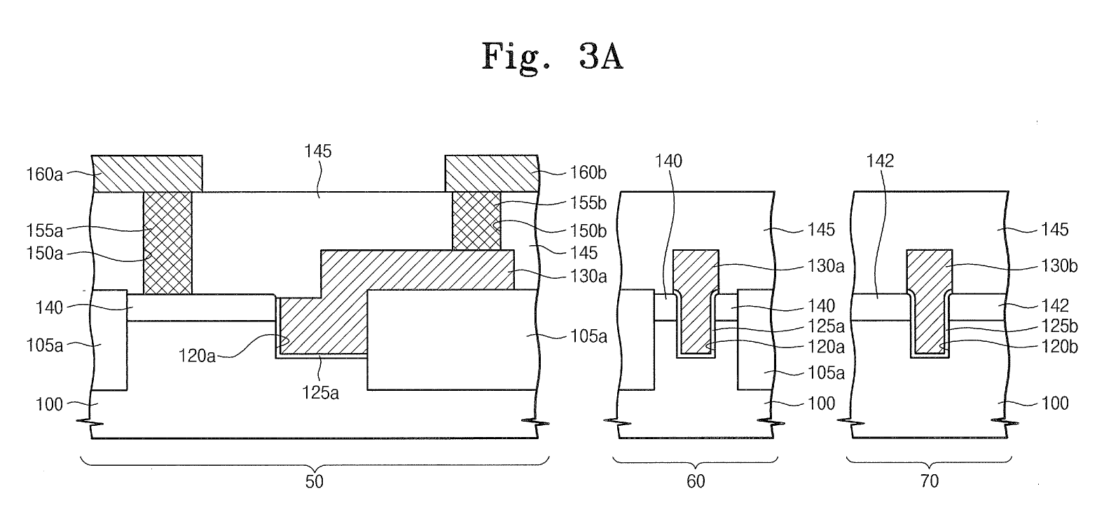

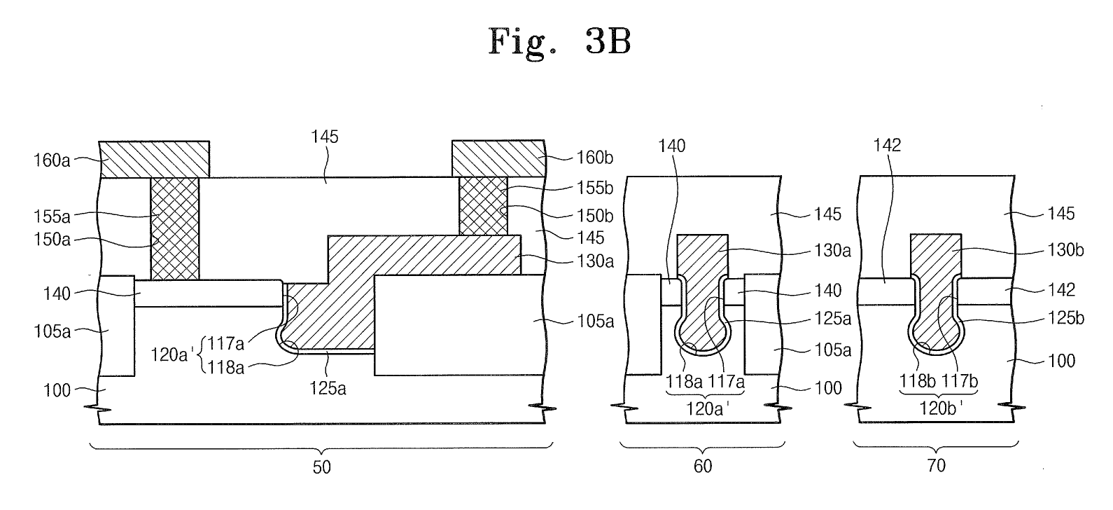

FIG. 2 is a plane view illustrating a semiconductor memory device in accordance with an embodiment of the present invention, and FIG. 3A is a sectional view taken along lines I-I′, II-II′, and III-III′ of FIG. 2. In FIG. 3A, the reference numeral ‘50’ denotes a section taken along line I-I′ of FIG. 2 and the reference numeral ‘60’ denotes a section taken along line II-II′ of FIG. 2. The reference numeral ‘70’ represents a section taken along line III-III′ of FIG. 2.

Referring to FIGS. 2 and 3A, a semiconductor substrate (hereinafter, ‘substrate’) 100 includes a fuse field A and a transistor field B. The fuse field A is provided to dispose a fuse of a fuse circuit therein. The transistor field B is provided to dispose a MOS field effect transistors (hereinafter, ‘transistor’) therein. For example, the transistor field B may include a DRAM cell including a transistor. Otherwise, the transistor field B may be a peripheral area where a transistor of a peripheral circuit is located. The semiconductor memory device having fuses according to embodiments of the present invention is not restrictive to a DRAM. Namely, the embodiments illustrated herein are applicable to many types of semiconductor memory devices including fuses and transistors. For instance, the semiconductor memory device by the present invention may be a DRAM, an SRAM, a flash memory, a ferroelectric memory, a magnetic memory, or a phase-change memory.

In the fuse field A, a fuse device isolation film 105a is disposed to define a fuse active region 103a. The fuse device isolation film 105a may be formed in a trench. A fuse recess region 120a is formed in the fuse active region 103a. The fuse recess region 120a includes inner sides and a bottom. The bottom of the fuse recess region 120a is leveled lower than the top of the fuse active region 103a. The inner sides of the fuse recess region 120a may be partially formed of the fuse active region 103a. The fuse recess region 120a may be adjacent to the fuse device isolation film 105a. In this case, the inner sides of the fuse recess region 120a, adjacent to the fuse device isolation film 105a, may be formed partially of the fuse device isolation film 105a. Otherwise, the fuse recess region 120a may be formed to be apart from the fuse device isolation film 105a. In this case, the inner sides of the fuse recess region 120a are formed of the fuse active region 103a.

A fuse conductor 130a is disposed within the fuse recess region 120a. A fuse insulation film 125a is interposed between the fuse conductor 130a and the inner sides of the fuse recess region 120a, which is formed of the fuse active region 103a. In addition, the fuse insulation film 125a is also interposed between the fuse conductor 130a and the bottom of the fuse recess region 120a. A fuse-doped region 140 is disposed in the fuse active region 103a adjacent to a side of the fuse conductor 130a. The doping region 140 is made up by injecting dopants therein. The fuse-doped region 140 may be formed of N-type dopants. Otherwise, the fuse-doped region 140 may be formed of P-type dopants. Between the fuse doped region 140 and the fuse conductor 130a is interposed the fuse insulation film 125a. The top of the fuse-doped region 140 is leveled with the top of the fuse active region 103a. The bottom of the fuse-doped region 140 is preferred to be higher than the bottom of the fuse recess region 120a. The fuse-doped region 140 is contactable to multiple sides of the fuse recess region 120a, which is apart from the fuse device isolation film 105a.

As illustrated herein, the fuse conductor 130a disposed within the fuse recess region 1120a may be divided into first and second parts. The first part of the fuse conductor 130a may be leveled with or lower than the top of the fuse active region 103a. The second part of the fuse conductor 130a extends upward to be higher than the top of the fuse active region 103a. The second part of the fuse conductor 130a may be adjacent to the fuse device isolation film 105a. Here, the second part of the fuse conductor 130a may extend over the fuse device isolation film 105a. Otherwise, the fuse conductor 130a may be disposed entirely within the fuse recess region 120a.

An interlevel insulation film 145 covers the substrate 100, as illustrated. The interlevel insulation film 145 may be formed of an oxide. First and second contact holes, 150a and 150b, are formed that extend through the interlevel insulation film 145. The first and second contact holes, 150a and 150b, are isolated from each other. The first contact hole 150a discloses the fuse doped region 140, while the second contact hole 150b discloses the fuse conductor 130a. The second contact hole 150b can expose the fuse conductor 130a placed on the fuse device isolation film 105a. Alternatively, if the fuse conductor 130a is located only in the fuse recess region 120a, then the second contact hole 150b may expose the fuse conductor 130a in the fuse recess region 120a.

On the interlevel insulation film 145, first and second interconnections 160a and 160b are arranged at spaced apart location. The first interconnection 160a is connected electrically to the fuse doped region 140 through the first contact hole 150a. The first interconnection 160a may contact directly with the fuse doped region 140 by extending downward to fill the first contact hole 150a. Otherwise, a first contact plug 155a may contact to the fuse doped region 140 by filling the first contact hole 150a, while the first interconnection 160a may contact to the top of the first contact plug 155a. The second interconnection 160b is electrically connected to the fuse conductor 130a through the second contact hole 150b. The second interconnection 160b may contact directly with the fuse conductor 130a by extending downward to fill the second contact hole 150b. Otherwise, a second contact plug 155b may contact the fuse conductor 130a by filling the second contact hole 150b, while the second interconnection 160b may contact to the top of the second contact plug 155b.

In the transistor field B, a transistor device isolation film 105b is patterned to define a transistor active region 103b. A gate electrode 130b intersects the transistor active region 103b. Between the gate electrode 130b and the transistor active region 103b is interposed a gate insulation film 125b. A channel recess region is provided in the transistor active region 103b under the gate electrode 13b. The bottom of the channel recess region 120b is leveled lower than the top of the transistor active region 103b. Here, the gate electrode 130b extends downward to fill the channel recess region 120b. The gate insulation film 125b is interposed between both sides of the gate electrode 130b and the channel recess region 120b, and between the gate electrode 130b and the bottom of the channel recess region 120b. Source/drain regions 142 are disposed in the transistor active region 103b at both sides of the gate electrode 130b. The bottoms of the source/drain regions 142 are preferred to be lower than the bottom of the channel recess region 120b. The interlevel insulation film 145 covers the substrate 100 in the transistor field B. Both sides and the bottom of the channel recess region 120b under the source/drain regions 142 correspond to a channel region.

Thus, in the transistor field B, a transistor is arranged having a recessed channel formed along the channel recess region 120b. Alternatively, a planar transistor may be disposed in the transistor field B.

The fuse conductor 130a may be formed of a conductive material such as doped polysilicon, metal (e.g., tungsten or molybdenum), metal nitride (e.g., titanium nitride or tantalum nitride), and metal silicide (e.g., tungsten suicide or cobalt silicide). The fuse conductor 130a may be formed of the same material as the gate electrode 130b. It is preferred for the fuse insulation film 125a to be made of oxide, such as thermal oxide. The gate insulation film 125b may also be formed of oxide, esp., such as thermal oxide. The fuse insulation film 125a and the gate insulation film 125b may be formed to have the same thickness. Otherwise, the fuse insulation film 125a and the gate insulation film 125b may have different thicknesses. In particular, it is preferred for the fuse insulation film 125a to be formed thinner than the gate insulation film 125b.

The source/drain regions 142 are doped with dopants (or ionic impurities). The source/drain regions 142 and the fuse-doped region 140 may be doped with the same type of dopants. Otherwise, the source/drain regions 142 and the fuse-doped region 140 may be doped with different types of dopants. The fuse-doped region 140 may be doped at a higher concentration relative to the source/drain regions 142. Otherwise, the fuse doped region 140 and the source/drain regions 142 may be doped at equivalent levels.

The contact plugs 155a and 155b include a conductive material. For instance, the contact plugs 155a and 155b may be formed using doped polysilicon as a conductive material, or a metal (e.g., tungsten etc.), or a conductive metal nitride (e.g., titanium nitride or tantalum nitride), or a metal silicide (e.g., tungsten silicide etc.). If the contact plugs 155a and 155b include doped polysilicon, then the dopant concentration in the doped polysilicon should be the same as the dopant concentration in the fuse doped region 140. The interconnections 160a and 160b include a conductive material such as metal.

In the aforementioned semiconductor memory device, the fuse-doped region 140 is associated with a first terminal of a fuse, while the fuse conductor 130a is associated with a second terminal of the fuse. An initial “open” condition of the fuse is the electrical isolation of the fuse conductor 130a that is provided by the fuse insulation film 125a. During a repair process, a fuse voltage is applied between the fuse doped region 140 and the fuse conductor 130a by way of the first and second interconnections 160a and 160b. During this application, the fuse voltage is set to a level high enough to break down the fuse insulation film 125a between the fuse doped region 140 and the fuse conductor 130a. When fuse insulation film 125a is broken by the fuse voltage, the fuse doped region 125a becomes electrically connected to the fuse conductor 130a to thereby form an electrical “short” between these two regions. The level of the fuse voltage necessary to breakdown the fuse insulation film 125a can be reduced by making the fuse insulation film 125a thinner than the gate insulation film 125b.

It will be understood by those skilled in the art, during a repair process, defective memory cells can be replaced with redundant cells by making selected fuses electrically conductive (i.e., breaking down the fuse insulation film 125a by the fuse voltage) to thereby deselect the defective memory cells. Alternatively, the process of breaking down the fuse insulating film 125a may be used to select normally operative cells that are not defective.

Alternative fuse patterns besides those shown in FIGS. 2 and 3A may also be used according to additional embodiments of the invention. For example, FIG. 3B is a sectional view of an alternative fuse pattern taken along lines I-I′, II-II′, and III-III′ of FIG. 2. Referring to FIG. 3B, a lower part 119a of a fuse recess region 120a′ may be formed wider than an upper part 117a of the fuse recess region 120a′. The upper part 117a of the fuse recess region 120a′ is defined as an upper fuse recess region, while the lower part 118a of the fuse recess region 120a′ is defined as a lower fuse access region. An inner side of the upper fuse recess region 117a is shaped in a linear pattern, while an inner side of the lower fuse recess region 118a is curved. The lower fuse recess region 118a is larger than the upper fuse recess region 118a in width. The inner sides of the upper and lower fuse recess regions 117a and 118a join with each other, as illustrated.

The fuse conductor 130a is disposed in the fuse recess region 118a with the fuse insulation film 125a interposed therebetween. The fuse conductor 130a fills up the lower fuse recess region 118a. The fuse conductor 130a at least partially fills the upper fuse recess region 117a. It is preferred for the bottom of the fuse-doped region 140 to be higher than the top of the lower fuse recess region 118a, as illustrated.

A lower part 118b of a channel recess region 120b′ is larger than an upper part 117b of the channel recess region 120b′ in width. The upper and lower parts, 117b and 118b, of the channel recess region 120b′ are defined as upper and lower channel recess regions, respectively. An inner side of the upper channel recess region 117b is shaped in a linear pattern, while an inner side of the lower channel recess region 118b is curved. The lower channel recess region 118b is larger than the upper channel recess region 117b in width. The inner sides of the upper and lower channel recess regions 117b and 118b with each other, as illustrated.

The gate electrode 130b fills the channel recess region 120b′, and the gate insulation film 125b lines the channel recess region 120b′, as illustrated. The bottoms of the source/drain regions 142 should be higher than the top of the lower channel recess region 118b. The curved shape of the lower channel recess region 118b increases the channel length of the transistor.

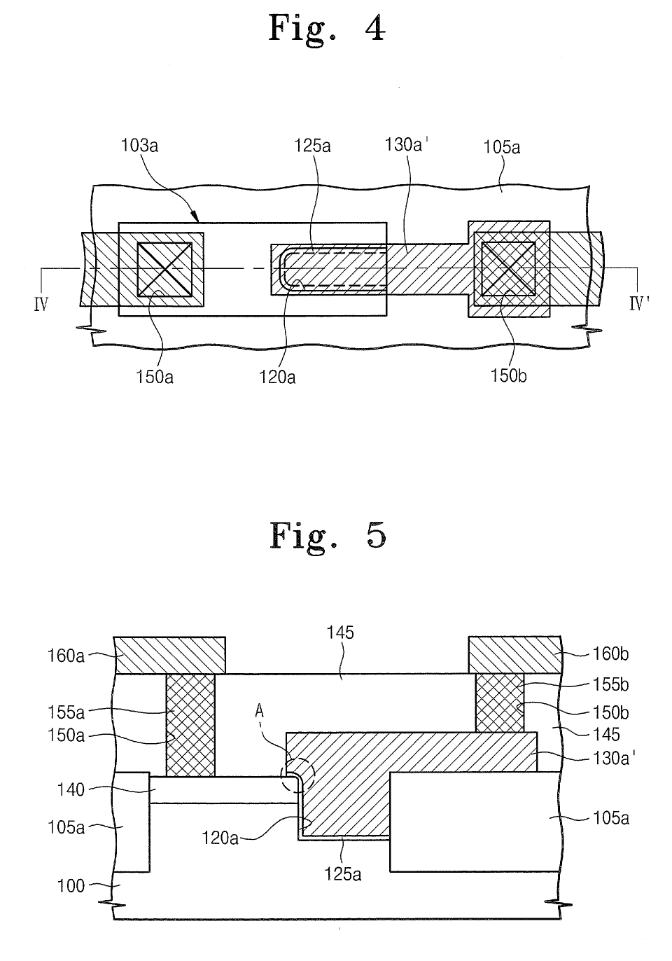

FIGS. 4-5 illustrate additional embodiments of the present invention. In particular, FIG. 4 is a plan view illustrating a semiconductor memory device according to an embodiment of the present invention, and FIG. 5 is a sectional view taken along line IV-IV′ of FIG. 4. Referring to FIGS. 4 and 5, a fuse conductor 130a′ extends to cover the top edge of the fuse doped region 140 adjacent to the fuse recess region 120a. Here, the fuse insulation film 125a extends between the fuse conductor 130a′ and the top edge of the fuse doped region 140. As illustrated, the fuse conductor 130a′ covers the top corner C of the fuse recess region 120a. The top corner C is corresponds to the corner at which the top of the fuse doped region 140 meets with the top of the inner side of the fuse recess region 120a.

The fuse insulation film 125a formed on the top corner C can be thinner than that formed on the inner side of the fuse recess region 120a. Accordingly, during a repair process, when the fuse voltage is applied between the fuse conductor 130a′ and the fuse doped region 140, the fuse insulation film 125a at the top corner C will break down more readily. As a result, lower fuse voltages may be used. Moreover, the top corner A can concentrate an electric field applied thereto by the fuse voltage, which further reduces the magnitude of the fuse voltage needed to cause breakdown.

According to still further embodiments of the present invention, the features illustrated by FIGS. 3B, 4 and 5 may be combined to yield additional fuse elements. For example, the fuse recess region 120a of the semiconductor memory device shown in FIGS. 4 and 5 may be replaced with the fuse recess region 120a′ shown in FIG. 3B. Further, the semiconductor memory device shown in FIGS. 4 and 5 may include the transistor 70 shown in FIG. 3A. Otherwise, the semiconductor memory device shown in FIGS. 4 and 5 may include the transistor 70 shown in FIG. 3B.

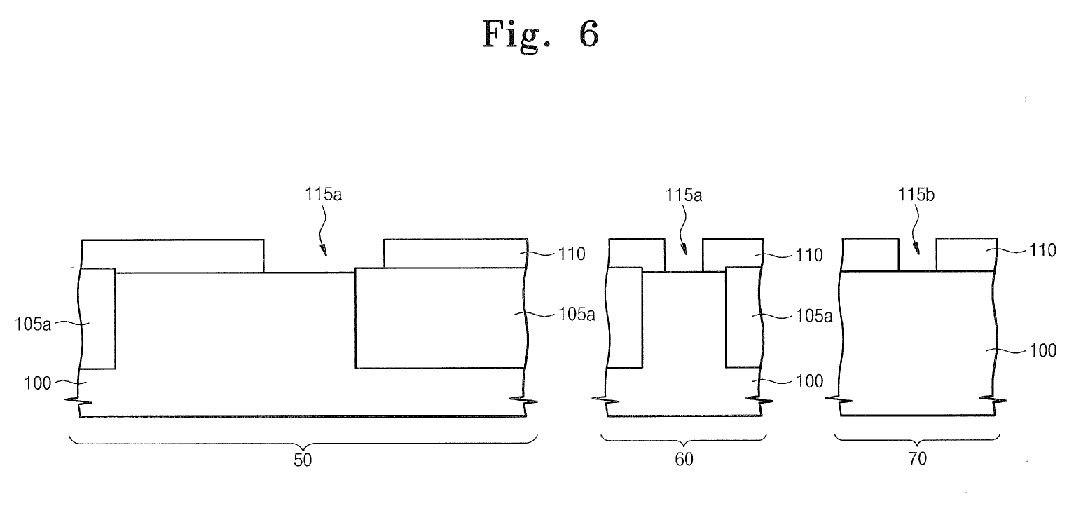

FIGS. 6 through 10 are sectional views taken along lines I-I′, II-II′, and III-III′ of FIG. 2, which illustrate a procedure of fabricating the semiconductor memory device, in accordance with embodiments of the present invention. First, referring to FIG. 6, the substrate 100 is prepared to include the fuse field A and the transistor field B shown in FIG. 2. The fuse field isolation film 105a is formed in the fuse field A, to thereby define the fuse active region 103a shown in FIG. 2. The transistor field isolation film 105b is formed in the transistor field B, to thereby define the transistor active region 103b shown in FIG. 2. The fuse and transistor device isolation films 105a and 105b may be formed at the same time. Then, a mask film 110 is arranged over the substrate 100. The mask film 110 may be made as a hard mask film. Otherwise, the mask film 110 may be formed of a photoresistive film. If the mask film 110 is formed as a hard mask film, then it may include a material having etching selectivity relative to the substrate 100. For instance, the mask film 110 may include a nitride film. Alternatively, the mask film 110 may further include a buffering oxide film interposed between the nitride film and the substrate 100.

Thereafter, the mask film 110 is patterned to form a first opening 115a partially disclosing the fuse active region 103a, and a second opening 115b partially disclosing the transistor active region 104b. The first opening 115a may be formed to further disclose a part of the fuse device isolation film 105a adjacent to the fuse active region 103a. As also, the second opening 115b is formed to further disclose a part of the transistor device isolation film 105b. If a transistor formed in the transistor field B is a transistor having a planar channel, then the second opening 115b may not be necessary.

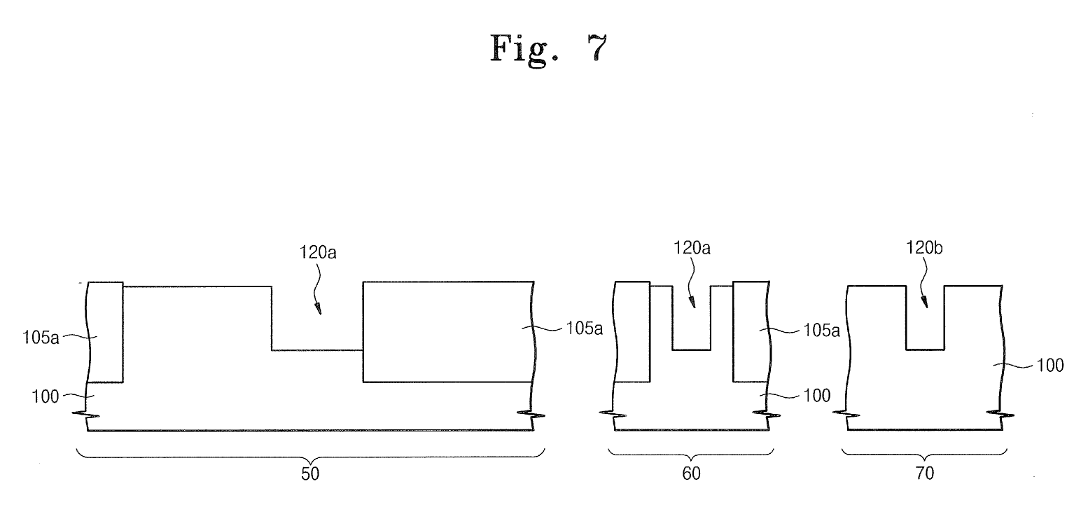

Next, referring to FIG. 7, the fuse and transistor active regions, 103a and 104b, exposed by the openings 115a and 115b are etched selectively and anisotropically to form the false recess region 120a and the channel recess region 120b. An etching ratio of the fuse and transistor active regions, in the anisotropic etching process, is higher than that of the fuse device isolation film 105a and the transistor active region 103b. The mask film 110 is then removed from the substrate 100.

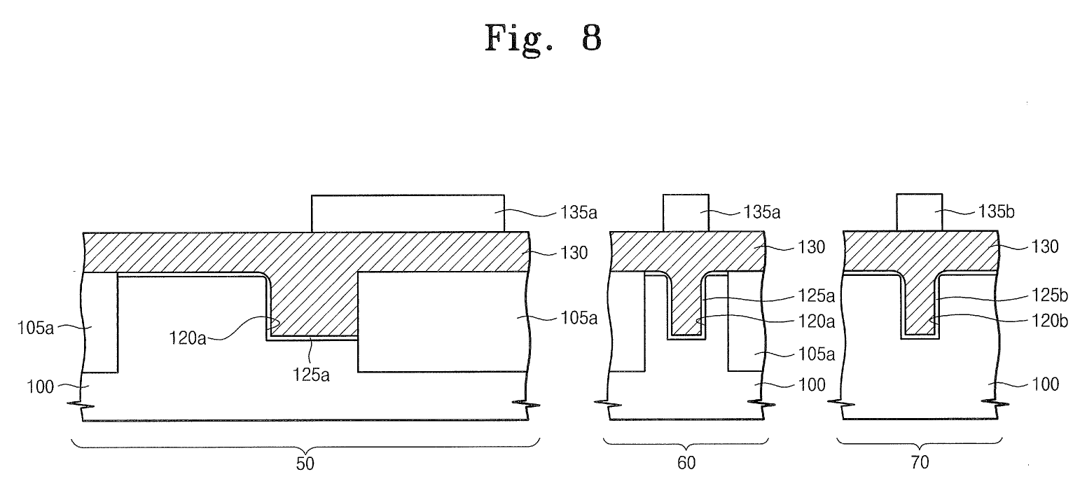

Referring to FIG. 8, the fuse insulation film 125a is deposited on the fuse active region 103a including the fuse recess region 210a. The gate insulation film 125b is formed on the transistor active region 103b including the channel recess region 120b. It is preferred for the fuse insulation film 125a to be made of an oxide (e.g., a thermal oxide). The gate insulation film 125b may also be formed of oxide (e.g., thermal oxide). The fuse and gate insulation films, 125a and 125b, may be simultaneously formed to the same thickness. Otherwise, the fuse and gate insulation films, 125a and 125b, may be formed to have different thicknesses from each other. S described above, it is preferred to form the fuse insulation film 125a thinner than the gate insulation film 125b. Now will be described a way of forming the fuse and gate insulation films 125a and 125b to have different thicknesses. First, the gate insulation film 125b is deposited over the substrate 100 including the fuse and transistor active regions 103a and 103b. The gate insulation film 125b on the fuse field is then removed to disclose the fuse active region 103a and the inner side and bottom of the fuse recess region 120a. Then, thermal oxidation is carried out to the substrate 100 to form the fuse insulation film 125a on the fuse active region 103a.

The fuse insulation film 125a is formed on the top of the fuse active region, and the inner side and bottom of the fuse recess region 120a. The insulation film 125b is settled on the transistor active region and the inner side and bottom of the channel recess region 120b. Thereafter, the conductive film 130 is deposited over the substrate 100, to thereby fill the fuse and channel recess regions 120a and 120b. First and second patterns, 135a and 135b, are formed on the conductive film 130 in the fuse and transistor fields. The first mask pattern 135a may be formed to partially cover the conductive film 130 filling the fuse recess region 120a. Additionally, the first mask pattern 135a may be formed to continuously cover a part of the conductive film 130 on the fuse device isolation film 105a. The first and second mask patterns, 135a and 135b, may be formed of a photoresistive film.

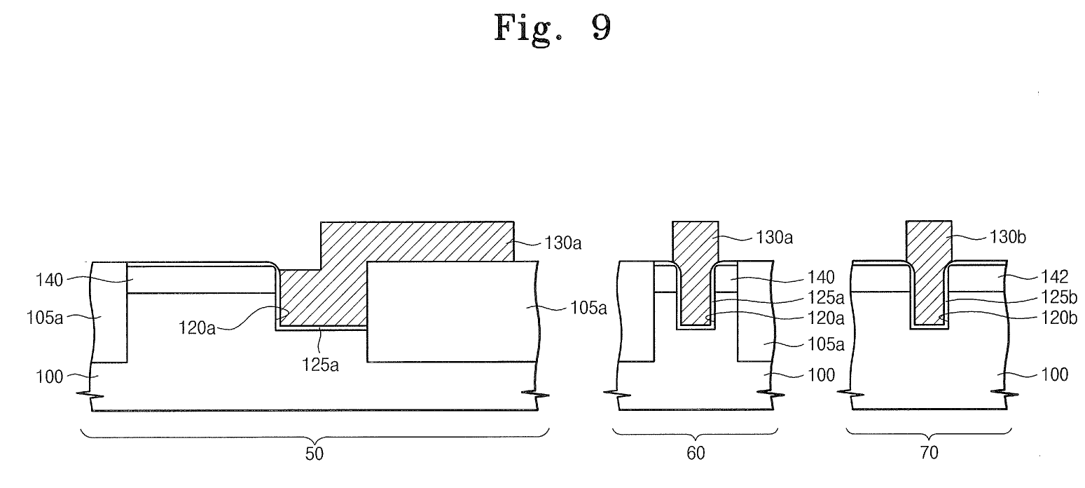

Next, referring to FIG. 9, the conductive film 130 is anisotropically etched using the first and second patterns 135a and 135b as a mask, to thereby define the fuse conductor 130a and the gate electrode 130b. The fuse conductor 130a and the gate electrode 130b are formed in the pattern illustrated by FIGS. 2 and 3A. The conductive film 130, which is uncovered by the first mask pattern 135a, but fills the fuse recess region 120a, is selectively etched to be a first part of the fuse conductor 130a. The first part of the fuse conductor 130a is disposed within the fuse recess region 120a, the top of which is leveled with or lower than the top of the fuse active region. The gate electrode 130b is formed under the second mask pattern 135b. Then, the first and second mask patterns 135a and 135b are removed from the substrate 100.

Then, using the fuse conductor 130a as a mask, dopant ions are injected into the fuse active region to form the fuse-doped region 140. Using the gate electrode 130b as a mask, dopant ions are injected into the transistor active region to form the source/drain regions 142. The fuse-doped region 140, as aforementioned, may include N or P-type dopants. The fuse doped region 140 and the source/drain regions 142 may be formed at the same time. Otherwise, it is permissible to form the source/drain regions 142 after completing the formation of the fuse-doped region 140. It is also permissible to form the fuse-doped region 140 after completing the formation of the source/drain regions 142.

During the dopant ion injection to form the fuse-doped region 140, the fuse insulation film 125a may remain on top of the fuse active region at the side of the fuse conductor 130a. In this case, the remaining fuse insulation film 125a may be used as an ion-injection buffering film. Otherwise, it is permissible, after completing the fuse conductor 130a, to form the fuse doped region 140 after removing the remaining fuse insulation film 125a from the side of the fuse conductor 130a by means of a wet etch process and then forming the ion-injection buffering film. The gate insulation film 125b may remain at both sides of the gate electrode 130b and be used as an ion-injection buffering film during the ion injection for the source/drain regions 142. Otherwise, it is permissible to form the source/drain regions 142 after removing the remaining gate insulation film 125b from both sides of the gate electrode 130b by means of a wet etch process and then forming the ion-injection buffering film.

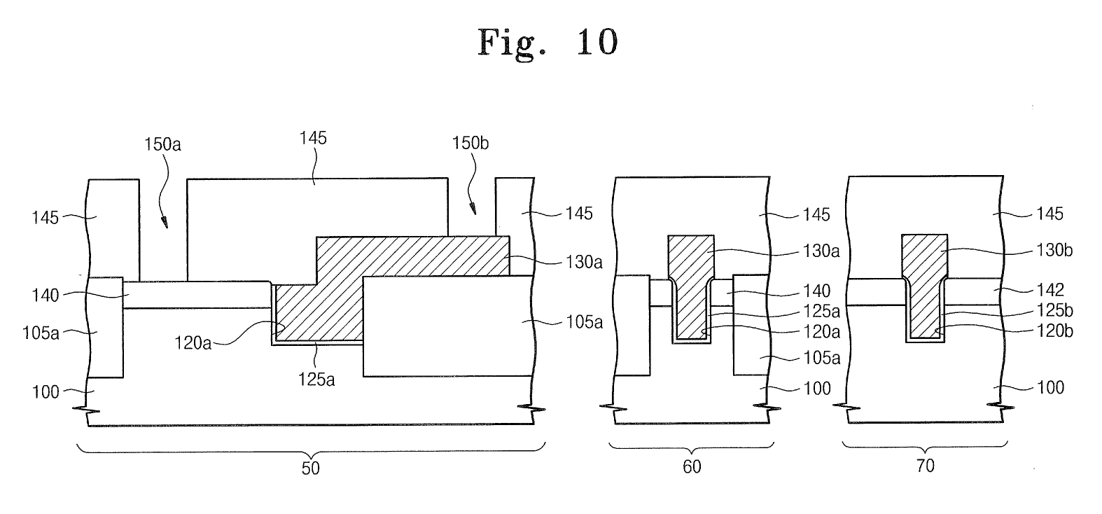

Thereafter, referring to FIG. 10, after forming the fuse doped region 140 and the source/drain regions 142, the top of the fuse active region at the side of the fuse conductor 130a, and the transistor active region at the side of the gate insulation film 130b are exposed by means of a wet etch process. Following this, the interlevel insulation film 145 is formed over the substrate 100. The interlevel insulation film 145 is patterned to form the first contact hole 150a that exposes the fuse doped region 140, and the second contact hole 150b that exposes the fuse conductor 130a. The first and second contact holes, 150a and 150b, can be formed at the same time or in sequence. Following this, the first and second contact plugs 155a and 155b, and the first and second interconnections 160a and 160b are formed to complete the structure of the semiconductor memory device shown in FIGS. 2 and 3A.

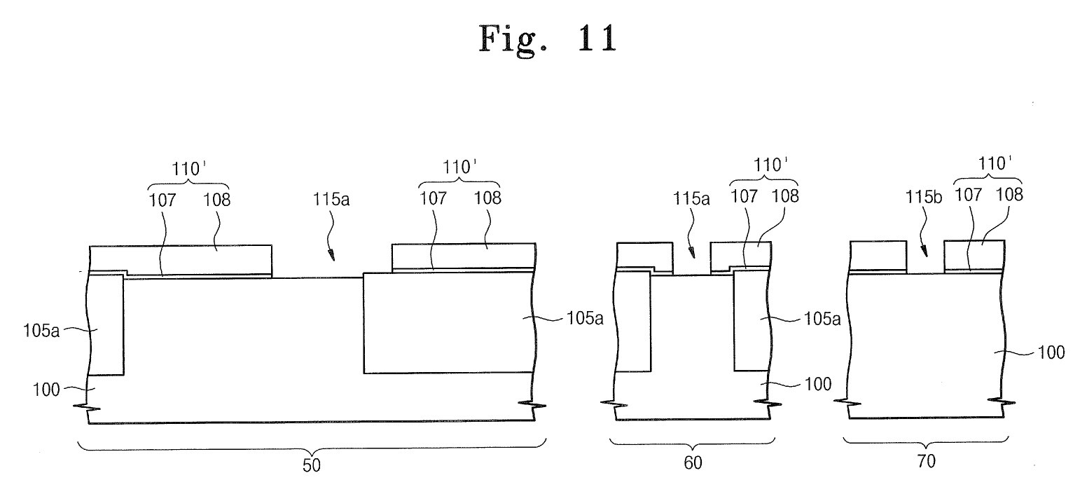

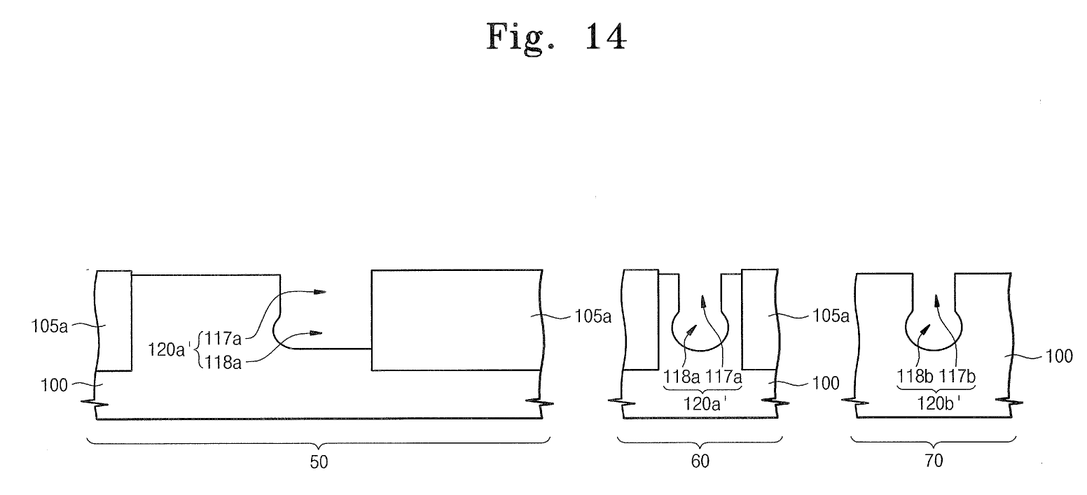

Next, a method of fabricating the semiconductor memory device shown in FIG. 3B will now be described. This method is similar to the method embodiment illustrated in FIGS. 6 through 11. FIGS. 11 through 15, which are sectional views taken along lines I-I′, II-II′, and III-III′ of FIG. 2, illustrate a procedure of fabricating the semiconductor memory device shown in FIG. 3B. Referring to FIG. 11, the steps of forming the fuse device isolation film 105a of the fuse field and the transistor field isolation film 105b is the same as that described with reference to FIG. 6. First, a mask film 110′ is deposited on the substrate 100 including the fuse and transistor active regions 103a and 103b. The mask film 110′ is formed by the first and second layers 107 and 108, which are stacked together in sequence. The second layer 108 is made of a material with an etching selectivity to the active regions 103a and 103b. Further, the second layer 108 may be formed of a material with etching selectivity to the first layer 107. For instance, the first layer 107 may be formed of an oxide, while the second layer 108 may be formed of a nitride.

Then, the mask film 110′ is patterned to form the first opening 115a, which partially exposes the fuse active region, and the second opening 115b, which partially exposes the transistor active regions. The first and second openings 115a and 115b are the same as the corresponding openings shown in FIG. 6.

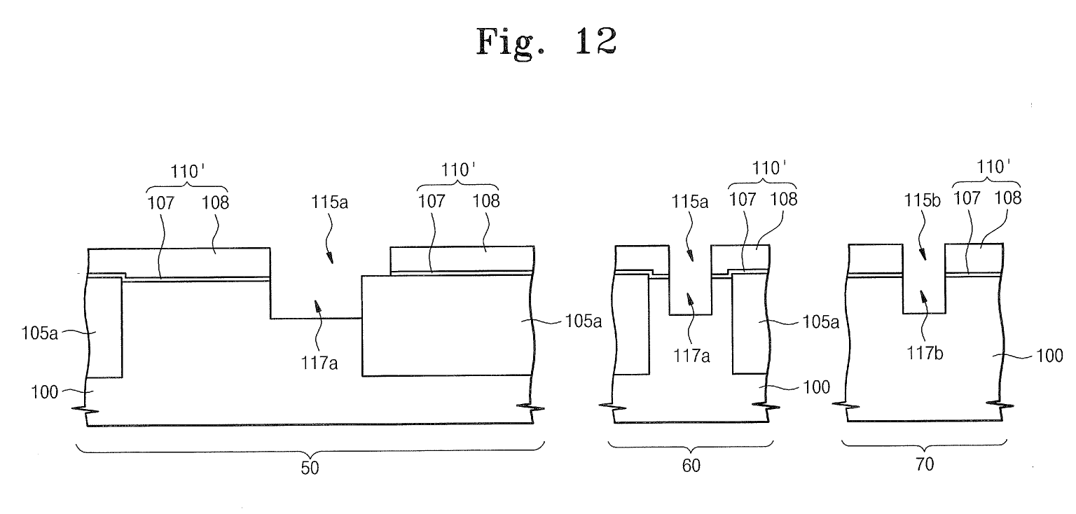

Thereafter, referring to FIG. 12, the fuse and transistor active regions exposed by the first and second openings 115a and 115b are etched selectively and anisotropically to form the upper fuse recess region 117a and the upper channel recess region 117b. The upper fuse and channel recess regions 117a and 117b may be shallower than the fuse and channel recess regions 120a and 120b of FIG. 7.

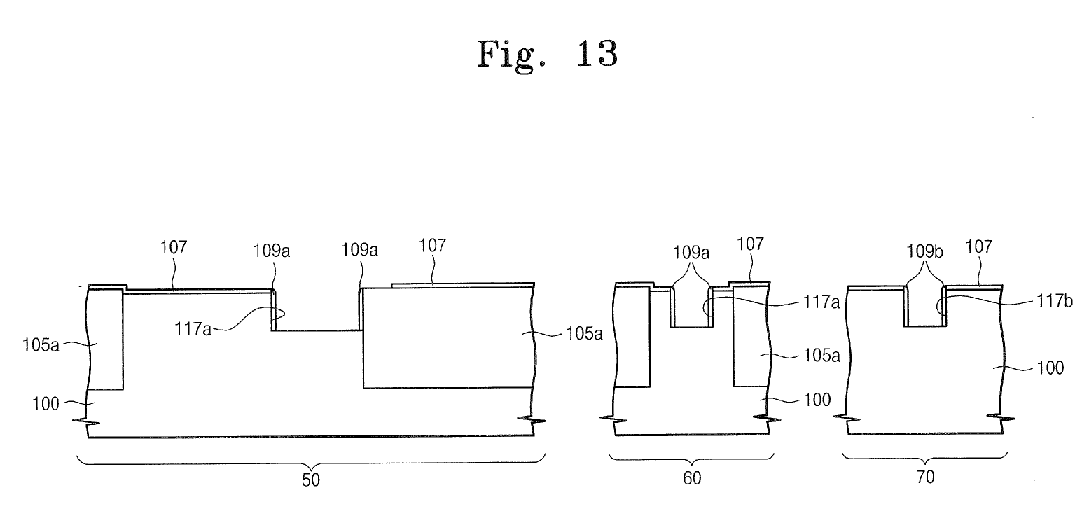

Referring now to FIG. 13, a spacer film is deposited over the substrate 100 by means of a chemical vapor deposition (CVD) process, for example. The spacer film is anisotropically etched until the bottoms of the upper fuse and channel recess regions 117a and 117b are exposed. This etching step results in the formation of first and second spacers 109a and 109b. The first spacer 109a covers the inner side of the upper fuse recess region 117a, while the second spacer 117b covers the inner side of the upper channel recess region 117b. The first and second spacers, 117a and 117b, are made of an oxide having an etching selectivity to the fuse and transistor active regions.

As illustrated herein, the disclosed bottoms of the upper fuse and channel recess regions 117a and 117b are isotropically etched to form the lower fuse and channel recess regions 118a and 118b. The upper and lower fuse channel recess regions 117a and 118a constitute the fuse recess region 120a′, while the upper and lower channel recess regions 117b and 118b constitute the channel recess region 120b′. The first layer 107 and the spacers 109a and 109b are removed from the substrate 100, thereby exposing the inner side and bottom of the fuse recess region 120a′ and the top of the fuse active region. The inner side and bottom of the channel recess region 120b′ and the top of the transistor active region are also exposed.

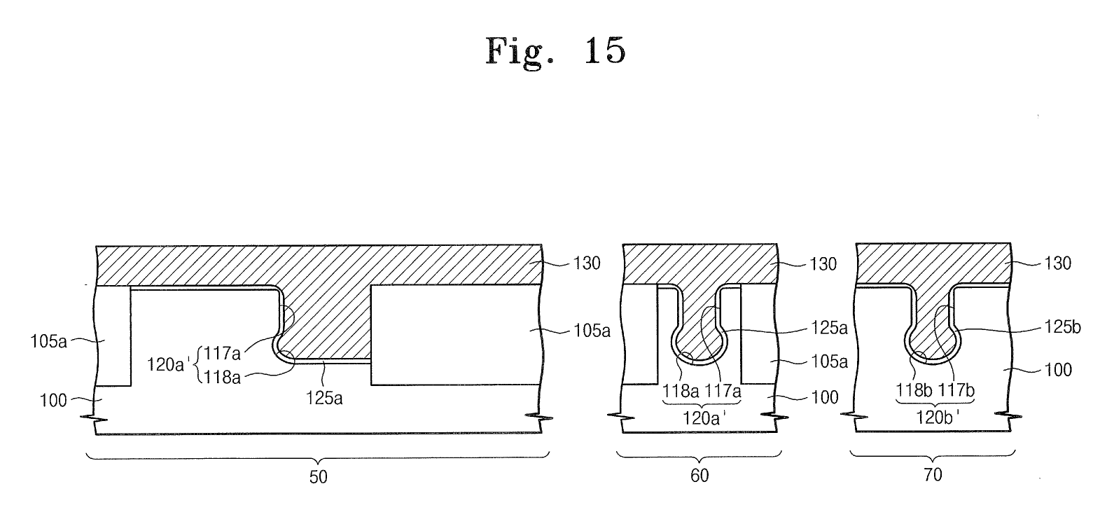

Next, referring to FIG. 15, the fuse insulation film 125a is formed on the fuse active region including the fuse recess region 120a′. The channel insulation film 125b is formed on the transistor active region including the transistor recess region 120b′. The fuse and gate insulation films, 125a and 125b, are formed in the same pattern illustrated in FIG. 8. The conductive film 130 is then deposited over the substrate 100 to thereby fill the fuse and channel recess regions 120a′ and 120b′. A process of patterning the conductive film 130 and the subsequent processing steps may be carried out as described previously with reference to FIGS. 8, 9, and 10.

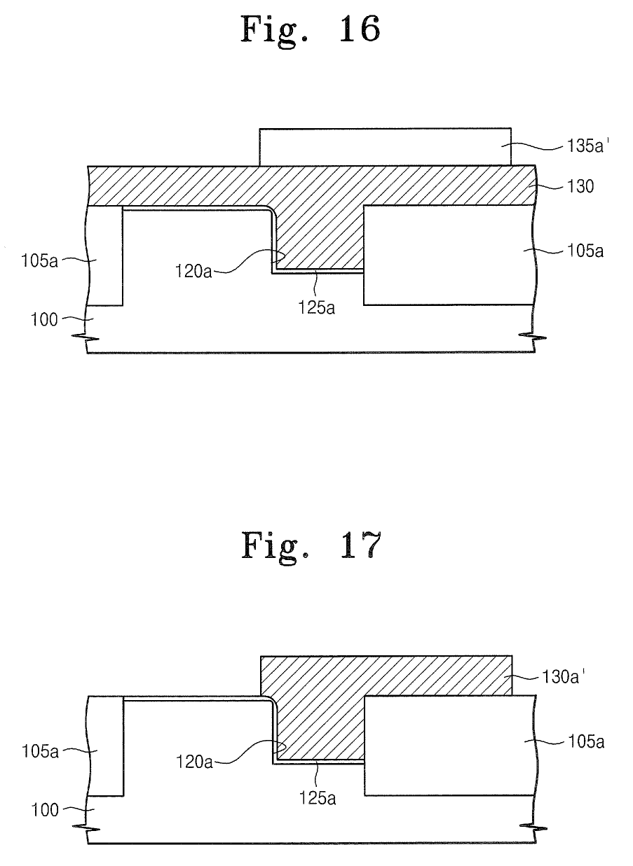

A method of fabricating the semiconductor memory device shown in FIGS. 4 and 5 will now be described. This method or procedure is similar to that described with reference to FIGS. 6 through 11. In particular, FIGS. 16 and 17, which are sectional views taken along line IV-IV′ of FIG. 4, illustrate a procedure of fabricating the semiconductor memory device shown in FIG. 4 or 5. First, referring to FIG. 16, the fuse recess region 120a is formed and the fuse insulation film 125a is formed on the fuse active region. The fuse insulation film 125a may be made of an oxide (e.g., a thermal oxide). Namely, thermal oxidation is carried out on the substrate including the fuse recess region 120a, resulting in the fuse insulation film 125a. During this, the fuse insulation film 125a formed at the top corner of the fuse recess region 120a is thinner than that formed on the fuse recess region 120a. The conductive film 130 is then deposited over the substrate 100 including the fuse insulation film 125a, to thereby fill the fuse recess region 120a. A first mask pattern 135a′ is then arranged on the conductive film 130 of the fuse recess region 130. The first mask pattern 135a′ may entirely cover a part of the conductive film 130 over the fuse recess region 120a. The first mask pattern 135a′ also covers the conductive film 130 over the top edge of the fuse active region adjacent to the fuse recess region 120a. In addition, the first mask pattern 135a′ may cover the conductive film 130 on the fuse device isolation film 105a adjacent to the fuse recess region 120a.

Referring now to FIG. 17, using the first mask pattern 135a′ as a mask, the conductive film 130 is anisotropically etched to the fuse conductor 130a′. The fuse conductor 130a′ is formed to cover the top corner of the fuse recess region 120a. Then, using the fuse conductor 130a′ as a mask, dopants ions are injected into the fuse active region to form the fuse doped region 140 of FIG. 5. An annealing process is also performed to activate dopants in the fuse-doped region 140. The annealing process aids the dopants to diffuse in the fuse doped region 140, which makes the fuse doped region 140 extend to contact with the inner side of the fuse recess region 120a (i.e., with the fuse insulation film 125a).

A process of forming the interlevel insulation film 145 and the subsequent processing steps may be carried out as described above with reference to FIG. 10.

In the drawings and specification, there have been disclosed typical preferred embodiments of the invention and, although specific terms are employed, they are used in a generic and descriptive sense only and not for purposes of limitation, the scope of the invention being set forth in the following claims.

1. An integrated circuit device, comprising:
a semiconductor substrate having a recess therein; and
a fuse element in said semiconductor substrate, said fuse element comprising:
a fuse insulation film lining a sidewall and a bottom of the recess;
a semiconductor fuse region of first conductivity type in said semiconductor substrate, said semiconductor fuse region extending to the sidewall of the recess; and
a fuse conductor on a portion of the fuse insulation film extending opposite the semiconductor fuse region.

2. The device claim 1, wherein a depth of the recess in said semiconductor substrate is greater than a depth of the semiconductor fuse region.

3. The device claim 1, further comprising a trench-based fuse isolation region that extends in said semiconductor substrate and defines a semiconductor fuse active region therein containing the recess.

4. The device claim 3, wherein the fuse conductor fills the recess and extends onto an upper surface of the trench-based fuse isolation region.

5. The device claim 3, wherein the recess is surrounding on at least three sides by the semiconductor fuse region.

6. The device claim 1, wherein said fuse element is a normally open fuse element.

7. The device claim 1, wherein a lower portion of the sidewall is recessed relative to an upper portion of the sidewall.

8. The device claim 1, wherein the fuse insulation film includes an insulation extension that extends from the sidewall onto an upper surface of the semiconductor fuse region; and wherein the fuse conductor extends onto the insulation extension.

9. The device claim 8, wherein the fuse insulation film has a nonuniform thickness adjacent a corner between the sidewall and the upper surface of the semiconductor fuse region.

10.-12. (canceled)

13. A semiconductor memory device comprising:
a substrate including a fuse field;
a fuse device isolation film disposed in the fuse field, and defining a fuse active region;
a fuse recess region formed at the fuse active region;
a fuse conductor disposed in the fuse recess region;
a fuse insulation film interposed between the fuse conductor and an inner side and bottom of the fuse recess region; and
a fuse doped region formed in the fuse active region beside the fuse conductor, with the fuse insulation film interposed therebetween.

14. The semiconductor memory device as set forth in claim 13, which further comprises:
an interlevel insulation film covering all the substrate; and
first and second interconnections disposed with being apart from each other on the interlevel insulation film,
wherein the first interconnection is electrically connected to the fuse doped region by way of a first contact hole penetrating the interlevel insulation film and the second interconnection is electrically connected to the fuse conductor by way of a second contact hole penetrating the interlevel insulation film.

15. The semiconductor memory device as set forth in claim 14, wherein the fuse conductor extends on the fuse device isolation film adjacent to the fuse active region and the second contact hole discloses the fuse conductor placed on the fuse device isolation film.

16. The semiconductor memory device as set forth in claim 13, wherein a lower part of the fuse recess region is wider than an upper part of the fuse recess region.

17. The semiconductor memory device as set forth in claim 13, wherein the fuse insulation film between the fuse doped region and the fuse conductor is one of first state and second state,
wherein the first state is a state of isolating the fuse doped region and the fuse conductor from each other and the second state is a state of being breakdown by a voltage applied between the fuse doped region and the fuse conductor, and
wherein when the fuse insulation film is conditioned in the second state, the fuse doped region and the fuse conductor are connected electrically to each other.

18. The semiconductor memory device as set forth in claim 13, wherein the fuse conductor extends to cover a top edge of the fuse doped region adjacent thereto and the fuse insulation film extends to be interposed between the fuse conductor and the top edge of the fuse-doped region.

19. The semiconductor memory device as set forth in claim 18, wherein a part of the fuse insulation film, which is formed at a top corner of the fuse recess region placed under the extending part of the fuse conductor, is thinner than another part of the fuse insulation film which is formed at an inner side of the fuse recess region.

20. The semiconductor memory device as set forth in claim 13, wherein the fuse-doped region is doped by N-type dopants or P-type dopants.

21. The semiconductor memory device as set forth in claim 13, wherein the substrate further includes a transistor field, further comprising;
a transistor device isolation film disposed in the transistor field, and defining a transistor active region;
a gate electrode intersecting the transistor active region;
a gate insulation film interposed between the gate electrode and the transistor active region; and
source/drain regions formed in the transistor active region at both sides of the gate electrode.

22. The semiconductor memory device as set forth in claim 21, wherein the gate electrode fills a channel recess region disposed at the transistor active region under the gate electrode, and the gate insulation film is interposed between the gate electrode and a inner surface of the channel recess region.

23. The semiconductor memory device as set forth in claim 22, wherein a lower part of the channel recess region is wider than an upper part of the channel recess region.

24. The semiconductor memory device as set forth in claim 21, wherein the fuse insulation film is equal to or smaller than the gate insulation film in thickness.

25. The semiconductor memory device as set forth in claim 21, wherein the fuse conductor includes the same material with the gate electrode.

26.-36. (canceled)
